(19) United States
(12) Patent Application Publication
(10) Pub. No.: US 2021/0326737 A1
(43) Pub. Date: Oct. 21, 2021

(54) SUPERCONDUCTING CIRCUIT ARCHITECTURE AND SUPERCONDUCTING QUANTUM CHIP INCLUDING A PLURALITY OF COUPLING DEVICES

(71) Applicant: Beijing Baidu Netcom Science and Technology Co., Ltd., Beijing (CN)

(72) Inventors: Lijing Jin, Beijing (CN); Runyao Duan, Beijing (CN)

(73) Assignee: Beijing Baidu Netcom Science and Technology Co., Ltd., Beijing (CN)

(21) Appl. No.: 17/036,352

(22) Filed: Sep. 29, 2020

(30) Foreign Application Priority Data
Apr. 21, 2020 (CN) 202010318557.5

(51) Int. Cl. G06N 10/00; H01L 39/22

(52) U.S. Cl. CPC G06N 10/00; H01L 39/223

(57) ABSTRACT

The present disclosure provides superconducting circuit architecture, a superconducting quantum chip, and a superconducting quantum computer including a plurality of coupling devices. The superconducting circuit architecture includes: a first qubit and a second qubit, and a first coupling device and a second coupling device. The first coupling device is coupled to the first qubit and the second qubit through a first connector, and the second coupling device is coupled to the first qubit and the second qubit through a second connector. The frequencies of the first qubit and the second qubit are between a frequency of the first coupling device and a frequency of the second coupling device, and a nonlinear strength of the first coupling device and a nonlinear strength of the second coupling device are opposite in sign.

### CROSS-REFERENCE TO RELATED APPLICATION

This application claims a priority to Chinese Patent Application No. 202010318557.5 filed on Apr. 21, 2020, the disclosures of which are incorporated in their entirety by reference herein.

### TECHNICAL FIELD

The present disclosure relates to the field of computers, in particular, to the field of quantum computing technology, and specifically to superconducting circuit architecture, a superconducting quantum chip, and a superconducting quantum computer including a plurality of coupling devices.

### BACKGROUND

In a superconducting circuit, qubits are coupled together in a specific manner, and a single-bit or two-bit quantum gate can be achieved by applying microwave pulses to the qubits.

Generally, there are many types of couplings the qubits together. In addition to the designed coupling between qubits, there may be some unavoidable parasitic couplings, in which these parasitic couplings will seriously affect the fidelity of the quantum gate, thereby limiting the performance of the entire quantum chip.

### SUMMARY

The present disclosure provides superconducting circuit architecture, a superconducting quantum chip, and a superconducting quantum computer including a plurality of coupling devices.

According to a first aspect, the present disclosure provides superconducting circuit architecture including a plurality of coupling devices, including a first qubit and a second qubit, and a first coupling device and a second coupling device, in which the first coupling device is coupled to the first qubit and the second qubit through a first connector, and the second coupling device is coupled to the first qubit and the second qubit through a second connector, and in which frequencies of the first qubit and the second qubit are between a frequency of the first coupling device and a frequency of the second coupling device, and a nonlinear strength of the first coupling device and a nonlinear strength of the second coupling device are opposite in sign.

According to a second aspect, the present disclosure provides a superconducting quantum chip, including the superconducting circuit architecture including the plurality of coupling devices of any one of the first aspect.

According to a third aspect, the present disclosure provides a superconducting quantum computer including the superconducting quantum chip of the second aspect.

According to the technical solution of the present disclosure, by introducing a plurality of coupling devices and setting the frequencies and nonlinear intensities of these coupling devices, different types of coupling between qubits can be regulated independently, thereby eliminating the parasitic couplings between these qubits in superconducting circuits, improving the fidelity of the single-bit quantum gate and the two-bit quantum gate realized in the superconducting circuit, and further improving the performance of the entire quantum chip. The present disclosure solves the problem that the parasitic coupling between qubits in the related art affects the fidelity of the single-bit quantum gate and the two-bit quantum gate implemented in the superconducting circuit.

It should be understood that the content described in this section is neither intended to identify key or important features of the embodiments of the present disclosure, nor is it intended to limit the scope of the present disclosure. Other features of the present disclosure will be easily understood through the following description.

### BRIEF DESCRIPTION OF THE DRAWINGS

The drawings are used to better understand the solution and do not constitute a limitation to the present disclosure. Among them:

FIG. 1 is a schematic view showing superconducting circuit architecture including a plurality of coupling devices according to a first embodiment of the present disclosure;

FIG. 2 is one of the schematic views showing the coupling relationship between qubits in the superconducting circuit architecture according to the first embodiment of the present disclosure;

FIG. 3 is a schematic view showing the structure of a superconducting circuit in a specific example according to the first embodiment of the present disclosure;

FIG. 4 is the other one of the schematic views showing the coupling relationship between qubits in the superconducting circuit architecture according to the first embodiment of the present disclosure.

### DETAILED DESCRIPTION

The exemplary embodiments of the present disclosure will be described below in conjunction with the drawings, which include various details of the embodiments of the present disclosure to be helpful for understanding, and should be considered as merely exemplary. Therefore, those skilled in the art should recognize that various changes and modifications may be made to the embodiments described herein without departing from the scope and spirit of the present disclosure. Similarly, for clarity and conciseness, the descriptions of well-known functions and structures are omitted in the following description.

### FIRST EMBODIMENT

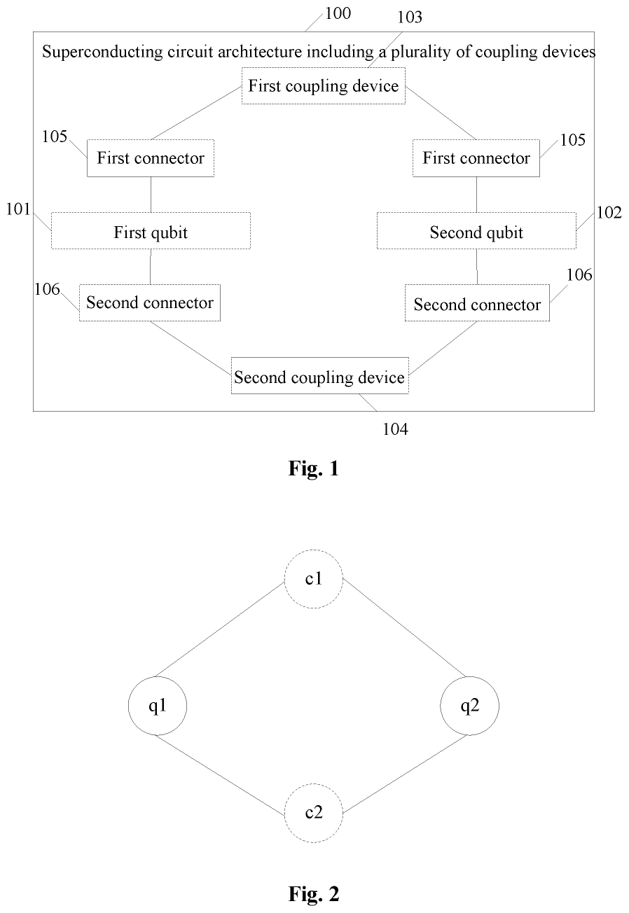

Referring to FIG. 1, FIG. 1 is a schematic view showing superconducting circuit architecture including a plurality of coupling devices according to a first embodiment of the present disclosure. As shown in FIG. 1, the superconducting circuit architecture 100 including a plurality of coupling devices includes: a first qubit 101 and the second qubit 102, and the first coupling device 103 and the second coupling device 104. The first coupling device 103 is r coupled to the first qubit 101 and the second qubit 102 through a first connector 105 respectively, and the second coupling device 104 is coupled to the first qubit 101 and the second qubit 102 through a second 106 connector respectively. The frequencies of the first qubit 101 and the second qubit 102 are between a frequency of the first coupling device 103 and a frequency of the second coupling device 104, and a nonlinear strength of the first coupling device 103 and a nonlinear strength of the second coupling device 104 are opposite in sign.

The first qubit 101 and the second qubit 102 both correspond to actual physical components. Among them, the structure of the first qubit 101 and the structure of the second qubit 102 may be the same or different, which will not be particularly limited herein.

In this embodiment, both the first qubit 101 and the second qubit 102 are described in detail by taking the transmon qubit as an example. In the superconducting circuit architecture, there are often two different types of coupling between transmon qubits, which can be defined as XY coupling and ZZ coupling respectively. The XY coupling refers to a coupling achieved by exchange a virtual photon between qubits, and the ZZ coupling means that the change of the state of one qubit will affect the frequency of another qubit.

The first coupling device 103 is coupled to the first qubit 101 and the second qubit 102 through the first connector 105 respectively, thereby generating an indirect coupling between the two qubits. In addition, the strength of the coupling between the two qubits varies along with the frequency of the first coupling device 103. In this way, the strength of the coupling between the two qubits can be regulated by changing the frequency of the first coupling device 103.

Specifically, in the superconducting circuit architecture, the first coupling device 103 is equivalent to creating a coupling path between two transmon qubits. In this way, effective XY coupling and ZZ coupling are generated between the transmon qubits, and the strength of the coupling can be regulated by changing the frequency of the first coupling device 103.

The second coupling device 104 is coupled to the first qubit 101 and the second qubit 102 through the second connector 106 respectively, thereby also generating an indirect coupling between the two qubits. In addition, the strength of the coupling between the two qubits varies along with the frequency of the second coupling device 104. In this way, the strength of the coupling between the two qubits can be regulated by changing the frequency of the second coupling device 104.

Specifically, in the superconducting circuit architecture, the second coupling device 104 is also equivalent to creating a coupling path between two transmon qubits. In this way, effective XY coupling and ZZ coupling are generated between the transmon qubits, and the strength of the coupling can be regulated by changing the frequency of the second coupling device 104.

In this way, two freedoms of adjustment are introduced, that is, the coupling strength of the XY coupling and the ZZ coupling between the two transmon qubits can be regulated by adjusting the frequencies of the first coupling device 103 and the second coupling device 104. Therefore, by introducing the first coupling device 103 and the second coupling device 104, and adjusting the frequencies of the first coupling device 103 and of the second coupling device 104, respectively, the coupling strengths of the XY coupling and the ZZ coupling between the two transmon qubits can be regulated independently.

In the regulation process, the purpose is usually to eliminate the parasitic coupling between two transmon qubits, and the parasitic coupling can be varied according to the function to be achieved by the superconducting circuit. For example, if a single-bit quantum gate is to be realized in the superconducting circuit, the XY coupling and the ZZ coupling between transmon qubits are both parasitic couplings between qubits. For another example, if a two-bit quantum gate is to be realized in the superconducting circuit, the XY coupling or the ZZ coupling between the transmon qubits is the parasitic coupling between the qubits. For example, the ZZ coupling in the iSWAP gate is the parasitic coupling between the qubits.

In addition, if the superconducting circuit is to be used to simulate, for example, the Bose-Hubbard model in the condensed matter physics, the purpose of regulation is to independently regulate both XY coupling and the ZZ coupling between qubits.

In order to realize that the coupling generated by the first coupling device 103 and the coupling generated by the second coupling device 104 can be effectively offset to eliminate parasitic coupling, for example, to eliminate XY coupling and the ZZ coupling for a single-bit quantum gate, and to eliminate the ZZ coupling for a two-bit quantum gate, such as an iSWAP gate. It is usually necessary to satisfy that the strength of the coupling generated by the first coupling device 103 and the strength of the coupling generated by the second coupling device 104 are opposite in sign.

Since the XY coupling between the transmon qubits is related to the frequencies of the first coupling device 103 and the second coupling device 104, it is necessary to limit the frequencies of the first coupling device 103 and the second coupling device 104, so that the strength of the XY coupling induced by a coupling device is a positive value, and the strength of the XY coupling strength induced by another coupling device is a negative value.

Moreover, since the ZZ coupling between transmon qubits is related to the nonlinear strengths of the first coupling device 103 and the second coupling device 104, it is necessary to limit the nonlinear strengths of the first coupling device 103 and the second coupling device 104, so that the strength of the ZZ coupling induced by a coupling device is a positive value, and the strength of the ZZ coupling induced by another coupling device is a negative value.

Specifically, frequencies of the first qubit 101 and the second qubit 102 are between a frequency of the first coupling device 103 and a frequency of the second coupling device 104, meanwhile a nonlinear strength of the first coupling device 103 and a nonlinear strength of the second coupling device 104 are opposite in sign.

In an embodiment, the frequency of the first coupling device 103 may be greater than the frequency of the first qubit 101 and greater than the frequency of the second qubit 102, and the frequency of the second coupling device 104 may be less than the frequency of the first qubit 101 and less than the frequency of the second qubit 102. At this time, the XY coupling between transmon qubits induced by the first coupling device 103 is a negative value, and the XY coupling between transmon qubits induced by the second coupling device 104 is a positive value. By independently adjusting the frequencies of the first coupling device 103 and the second coupling device 104, the XY coupling between the transmon qubits can be hopefully eliminated.

Meanwhile, in this embodiment, the nonlinear strength of the first coupling device 103 may be a positive value, and the nonlinear strength of the second coupling device 104 may be a negative value. At this time, the ZZ coupling between transmon qubits induced by the first coupling device 103 is a positive value, and the ZZ coupling between transmon qubits induced by the second coupling device 104 is a negative value. By independently adjusting the frequencies of the first coupling device 103 and the second coupling device 104, the ZZ coupling between the transmon qubits can be hopefully eliminated.

Of course, in practical applications, there are other embodiments to set the frequencies and nonlinear intensities of the first coupling device 103 and the second coupling device 104, which only need to satisfy that frequencies of the first qubit 101 and the second qubit 102 are between a frequency of the first coupling device 103 and a frequency of the second coupling device 104, and meanwhile a nonlinear strength of the first coupling device 103 and a nonlinear strength of the second coupling device 104 are opposite in sign.

In this embodiment, by introducing two freedoms of adjustment, i.e., introducing the first coupling device 103 and the second coupling device 104, and by adjusting the frequencies of the first coupling device 103 and the second coupling device 104, respectively, the coupling strengths of the XY coupling and the ZZ coupling between two transmon qubits can be regulated independently. Furthermore, by limiting the frequencies and nonlinear strengths of the first coupling device 103 and the second coupling device 104, the frequencies of the first qubit 101 and the second qubit 102 are between a frequency of the first coupling device 103 and a frequency of the second coupling device 104, a nonlinear strength of the first coupling device 103 and a nonlinear strength of the second coupling device 104 are opposite in sign. The XY coupling and/or the ZZ coupling can be hopefully eliminated, thereby eliminating the parasitic couplings between the single-bit quantum gate and the two-bit quantum gate achieved by the superconducting circuit, improving the fidelity of the quantum gate, and further improving the performance of the entire quantum chip.

Since the coupling strengths of the XY coupling and ZZ coupling between the transmon qubits in the superconducting circuit architecture can be independently regulated, the superconducting circuit can achieve a single-bit quantum gate of high fidelity in the case that the XY coupling and the ZZ coupling between the transmon qubits are completely eliminated. In the case that only the ZZ coupling between transmon qubits is eliminated, the superconducting circuit can realize a two-bit quantum gate of high fidelity, and the XY coupling strength between transmon qubits can also be freely regulated according to requirements. Moreover, the superconducting circuit can also simulate, for example, the Bose-Hubbard model in condensed matter physics. Therefore, the superconducting circuit can realize a plurality of applications according to the actual situation of regulation, thereby increasing the application range of the superconducting circuit.

In addition, since the different types of coupling between qubits in the superconducting circuit architecture can be independently regulated or even eliminated, the scalability and the pulse calibration process of the entire superconducting circuit will no longer be affected by a crosstalk, thereby making it easier.

In practical applications, the first coupling device 103 may be a resonant cavity or a qubit. The second coupling device 104 may be a resonant cavity or a qubit. For ease of integration, preferably, both the first coupling device 103 and the second coupling device 104 may be qubits.

In order to enable the first coupling device 103 to be effectively coupled to the first qubit 101 and the second qubit 102, respectively, the first connector 105 may include at least one of the following components: a capacitor, a Josephson junction, and a resonant cavity. In order to enable the second coupling device 104 to be effectively coupled to the first qubit 101 and the second qubit 102, the second connector 102 may also include at least one of the following components: a capacitor, a Josephson junction, and a resonant cavity. In this embodiment, both the first connector 105 and the second connector 106 are described in detail by taking a capacitor as an example.

It should be noted that the superconducting circuit architecture in the present disclosure refers to a circuit achieved by using superconducting devices, that is, all the components used in the superconducting circuit are made of superconducting materials. Moreover, the qubits and parameter intervals in the present disclosure are based on the existing superconducting circuit technology, so their reliability can be guaranteed.

Optionally, the first coupling device 103 and the second coupling device 104 are both qubits prepared to a ground state.

In this embodiment, the first coupling device 103 and the second coupling device 104 are also qubits. The qubit achieved by the first qubit 101 can be called a computational qubit q1, and the qubit achieved by the second qubit 102 can be called a computational qubit q2. At the same time, the qubit achieved by the first coupling device 103 can be called a coupled qubit c1, and the qubit achieved by the second coupling device 104 can be called a coupled qubit c2.

Referring to FIG. 2, FIG. 2 is one of the schematic views showing the coupling relationship between qubits in the superconducting circuit architecture according to the first embodiment of the present disclosure. As shown in FIG. 2, the computational qubits are marked with solid circles, and the coupled qubits are marked with dash circles.

Specifically, the coupled qubit c1 is coupled to the computational qubit q1 and the computational qubit q2, respectively, thereby generating an indirect coupling between the computational qubit q1 and the computational qubit q2. Moreover, by adjusting the frequency of the coupled qubit c1, the strength of the coupling between the computational qubit q1 and the computational qubit q2 can be adjusted. At the same time, the coupled qubit c2 is also coupled to the computational qubit q1 and the computational qubit q2, respectively, thereby generating an indirect coupling between the computational qubit q1 and the computational qubit q2. Moreover, by adjusting the frequency of the coupled qubit c2, the strength of the coupling between the computational qubit q1 and the computational qubit q2 can also be adjusted.

In this way, by introducing two freedoms of adjustment, that is, introducing the coupled qubit c1 and the coupled qubit c2, and by adjusting the frequencies of the coupled qubit c1 and the coupled qubit c2, respectively, the coupling strengths of the XY coupling and the ZZ coupling between the two transmon qubits can be independently regulated. Furthermore, by limiting the frequencies and nonlinear strengths of the coupled qubit c1 and the coupled qubit c2, the frequencies of the computational qubit q1 and the computational qubit q2 are between a frequency of the coupled qubit c1 and a frequency of the coupled qubit c2, a nonlinear strength of the coupled qubit c1 and a nonlinear strength of the coupled qubit c2 are opposite in sign. The XY coupling and/or the ZZ coupling can be hopefully eliminated, thereby eliminating the parasitic couplings between the single-bit quantum gate and the two-bit quantum gate achieved by the superconducting circuit architecture, improving the fidelity of the quantum gate, and further improving the performance of the entire quantum chip.

It should be noted that the coupled qubit c1 and the coupled qubit c2 are qubits prepared to the ground state. As an auxiliary qubit, it is necessary to avoid high-energy level leakage of the coupled qubit as much as possible, to avoid affecting the fidelity of the quantum gate.

In addition, in the superconducting circuit architecture, it is required that the coupling between the computational qubit and the coupled qubit is a diffuse coupling. The diffuse coupling means that the strength of the coupling between the computational qubit and the coupled qubit is much less than the frequency difference between them. In this way, the noise from the coupled qubit can be suppressed, and thus can only be used as an auxiliary qubit.

In this embodiment, by designing the coupling device into a structure similar to that of the qubit, the superconducting circuit architecture is easier to be integrated.

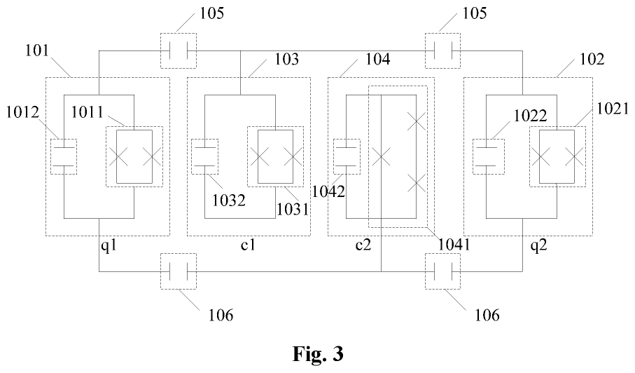

Referring to FIG. 3, FIG. 3 is a schematic view showing the structure of a superconducting circuit in a specific example according to the first embodiment of the present disclosure. As shown in FIG. 3, the nonlinear strength of the first coupling device 103 and the nonlinear strength of second coupling device 104 are opposite in sign, their design structures are also different. In a specific example, the nonlinear strength of the first coupling device 103 is a negative value, which can be achieved by a transmon qubit, and the nonlinear strength of the second coupling device 104 is a positive value, which can be achieved by another qubit, e.g., a qubit called capacitive-shunted flux qubit.

Specifically, the first coupling device 103 includes a first superconducting quantum interference device 1031, and a first capacitor 1032 connected in parallel with the first superconducting quantum interference device. The first superconducting quantum interference device 1031 includes two Josephson junctions connected in parallel, for adjusting the frequency of the first coupling device 103 by applying a magnetic flux. The second coupling device 104 includes a second superconducting quantum interference device 1041, and a second capacitor 1042 connected in parallel with the second superconducting quantum interference device 1041. The second superconducting quantum interference device 1041 is composed of two Josephson devices connected in series and another Josephson junction connected in parallel therewith, for adjusting the frequency of the second coupling device 104 by applying a magnetic flux.

In this embodiment, by designing the first coupling device 103 and the second coupling device 104 into different structures, the nonlinear strength of the first coupling device 103 and the nonlinear strength of the second coupling device 104 can be realized to be opposite in sign. Moreover, by applying a magnetic flux to the first superconducting quantum interference device 1031 and the second superconducting quantum interference device 1041, the applied magnetic flux directly affects the Josephson energy of the coupled qubit, thereby changing the frequency of the coupled qubit, further conveniently adjusting the frequency of the coupled qubit by adjusting the magnetic flux passing through the superconducting quantum interference device.

Optionally, the first qubit 101 includes a third superconducting quantum interference device 1011, for adjusting the frequency of the first qubit 101 by applying a magnetic flux; and the second qubit 102 includes a fourth superconducting quantum interference device 1021, for adjusting the frequency of the second qubit 102 by applying a magnetic flux.

In this embodiment, by using the third superconducting quantum interference device 1011 and the fourth superconducting quantum interference device 1021, the frequency of the first qubit 101 and the second qubit 102 can be adjusted by applying a magnetic flux, respectively.

Optionally, the third superconducting quantum interference device 1011 and the fourth superconducting quantum interference device 1021 both include two Josephson junctions connected in parallel.

In this embodiment, by applying a magnetic flux to the third superconducting quantum interference device 1011 and the fourth superconducting quantum interference device 1021, the applied magnetic flux directly affects the Josephson energy of the computational qubit, thereby conveniently adjusting the frequency of the computational qubit by adjusting the magnetic flux passing through the superconducting quantum interference device, which lays the foundation for realizing the coupling between the coupled qubit and the computational qubit.

Optionally, the first qubit 101 and the second qubit 102 both include a noise reduction component, for reducing a noise of charge fluctuations in an environment where the qubit is located. As shown in FIG. 3, the first qubit 101 includes a noise reduction component 1012, and the second qubit 102 includes a noise reduction component 1022.

Optionally, the first qubit 101 further includes a third capacitor connected in parallel with the third superconducting quantum interference device 1011, for reducing a noise of charge fluctuations in an environment where the qubit is located; and the second qubit further 102 includes a fourth capacitor connected 1021 in parallel with the fourth superconducting quantum interference device, for reducing a noise of charge fluctuations in an environment where the qubit is located.

As shown in FIG. 3, the noise reduction component 1012 may be a third capacitor, and the noise reduction component 1022 may be a fourth capacitor.

Optionally, the superconducting circuit architecture further includes a third coupling device, in which the third coupling device is coupled to the first qubit 101 and the second qubit 102 through a third connector respectively.

In this embodiment, the superconducting circuit architecture of the above embodiment can be extended. Specifically, when there are N different types of coupling between the first qubit 101 and the second qubit 102, that is, between two computational qubits, N is greater than 2, then at least one third coupling device can be introduced, and a total of N coupling devices can be introduced, taking the first coupling device 103 and the second coupling device 104 into account.

The third coupling device is coupled to the first qubit 101 and the second qubit 102, respectively, in a similar coupling manner to the first coupling device 103 and the second coupling device 104, which will not be repeated herein.

Each coupling device introduced can generate a coupling path between two computational qubits, and thus can independently regulate the strength of the coupling between the two computational qubits by adjusting the frequency of the coupling device. Therefore, by introducing N coupling devices, the superconducting circuit can independently regulate the strength of the coupling between two computational qubits in N freedoms, so that N different types of coupling between two computational qubits can be independently regulated, and one or several or even all couplings can be completely eliminated when necessary, thereby eliminating the parasitic coupling between two computational qubits, improving the fidelity of the single-bit quantum gate and two-bit quantum gate implemented in superconducting circuits, and further improving the performance of the entire quantum chip.

Optionally, the superconducting circuit architecture further includes: a third qubit, a fourth coupling device, and a fifth coupling device, in which the fourth coupling device is coupled to a target computational qubit and the third qubit through a fourth connector respectively, and the fifth coupling device is coupled to the target computational qubit and the third qubit through a fifth connector respectively, and in which the target computational qubit is one of the first qubit 101 and the second qubit 102.

In this embodiment, the superconducting circuit architecture in the above embodiment can be extended. Specifically, the superconducting circuit architecture in the above embodiment is used as a basic unit for extension, in order to support more complex tasks.

The number of third qubits may be at least one, and each of the third qubits may be paired with a target computational qubit, and the target computational qubit is the first qubit 101 or the second qubit 102. At the same time, the fourth coupling device is respectively coupled to the two computational qubits, and the fifth coupling device is also respectively coupled to the two computational qubits, so that the XY coupling and the ZZ coupling between the two computational qubits can be independently regulated, so as to eliminate the parasitic coupling between the two computational qubits.

In this way, in the superconducting circuit architecture in this embodiment, two coupled qubits are introduced between every two adjacent computational qubits. And, by independently adjusting the frequency of the coupled qubits, it is possible to regulate the XY coupling and the ZZ coupling between the computational qubits, to eliminate the parasitic coupling between every two adjacent computational qubits, so that a plurality of quantum gates of high fidelity can be achieved in the superconducting circuit, thereby supporting more complex tasks.

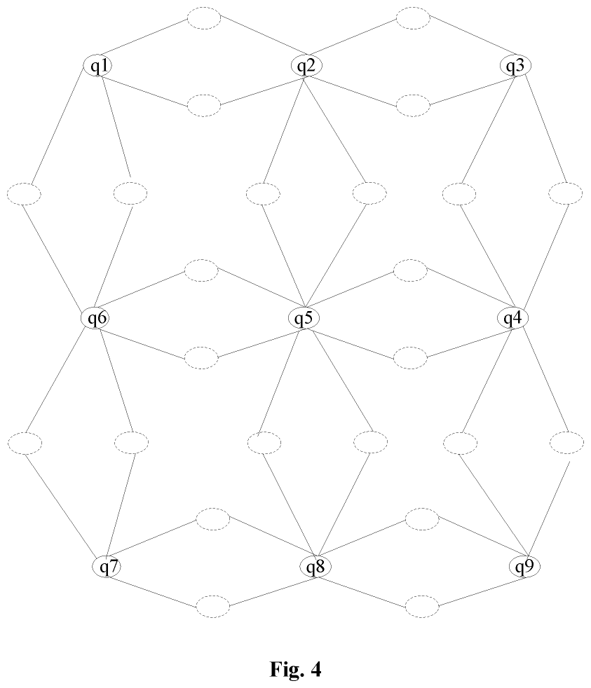

Referring to FIG. 4, FIG. 4 is the other one of the schematic views showing the coupling relationship between qubits in the superconducting circuit architecture according to the first embodiment of the present disclosure. As shown in FIG. 4, the computational qubits are marked with solid circles, and the coupled qubits are marked with dash circles. As shown in FIG. 4, the superconducting circuit architecture includes nine computational qubit architectures. There are two coupled qubits between every two adjacent computational qubits, thereby generating two coupling paths between every two adjacent computational qubits.

Each computational qubit is connected to eight adjacent coupled qubits, and quantum gate operations can be realized between two adjacent computational qubits. The XY coupling and the ZZ coupling between two adjacent computational qubits can be independently regulated by adjusting the frequency of the two coupled qubits set between them, to eliminate the parasitic coupling between every two adjacent computational qubits, so that a plurality of quantum gates of high fidelity can be implemented in the superconducting circuit, thereby supporting more complex tasks.

It should be noted that the various optional embodiments in the superconducting circuit architecture according to the present disclosure can be implemented in combination with each other or can be implemented separately, which will not be limited in the present disclosure.

The working principle of superconducting circuit architecture including a plurality of coupling devices will be described in detail below.

In order to be able to clearly understand the working principle of the above technical solution, we start from the Hamiltonian of the designed superconducting circuit and analyze it. Taking the qubit architecture described in FIG. 2 as an example, the Hamiltonian describing the superconducting circuit is shown in the following equation (1):

$$\hat{H} = {\sum }_{i , j = 1}^{2} ( {ω}_{qi} {\hat{a}}_{qi}^{†} {\hat{a}}_{qi} + \frac{{α}_{qi}}{2} {\hat{a}}_{qi}^{†} {\hat{a}}_{qi}^{†} {\hat{a}}_{qi} {\hat{a}}_{qi} + {ω}_{cj} {\hat{a}}_{cj}^{†} {\hat{a}}_{cj} + \frac{{α}_{cj}}{2} {\hat{a}}_{cj}^{†} {\hat{a}}_{cj}^{†} {\hat{a}}_{cj} {\hat{a}}_{cj} + {g}_{ij} ( {\hat{a}}_{cj}^{†} {\hat{a}}_{cj} + {\hat{a}}_{qi} {\hat{a}}_{cj}^{†} ) ) \qquad ( 1 )$$

In the above equation (1), the qubits are all described by the Duffing harmonic oscillator model, in which the first two items describe the items of the computational qubits, the third and fourth items describe the items of the coupled qubits, and the last item describes the coupling between the i th computational qubit and the j th coupled qubit, in which gᵢⱼ is the corresponding coupling strength.

Specifically, ω^{qi} is the frequency of the i th computational qubit, ω_{ct} represents the frequency of the i th coupled qubit, α_{qi} is the nonlinear strength of the i th computational qubit, α_{ci} is the nonlinear strength of the i th th coupled qubit, â_{qi}^{†} and â_{qi} the ladder operators describing the i th computational qubit, and â_{ci}^{†} and â_{ci} are the ladder operators describing the i th coupled qubit.

It should be noted that in this superconducting circuit, the coupling between the computational qubit and the coupled qubit is required to be a diffuse coupling. The diffuse coupling means that the strength of the coupling between the computational qubit and the coupled qubit is much less than the frequency difference between them. In this way, the noise from the coupled qubit can be suppressed, and thus can only be used as an auxiliary qubit.

Based on the above conditions, the Schrieffer-Wolff transformation is performed on the above equation (1), and the purpose is to separate the target quantum gate coupling term from the parasitic coupling term, so as to obtain the following equation (2):

$$\hat{H} \approx {\sum }_{i , j = 1}^{2} ( {\tilde{ω}}_{qi} {\hat{a}}_{qi}^{†} {\hat{a}}_{qi} + \frac{{\tilde{α}}_{qi}}{2} {\hat{a}}_{qi}^{†} {\hat{a}}_{qi}^{†} {\hat{a}}_{qi} {\hat{a}}_{qi} + {\tilde{ω}}_{cj} {\hat{a}}_{cj}^{†} {\hat{a}}_{qi} + \frac{{\tilde{α}}_{cj}}{2} {\hat{a}}_{cj}^{†} {\hat{a}}_{cj}^{†} {\hat{a}}_{cj} {\hat{a}}_{cj} ) + [ \frac{{g}_{11} {g}_{21}}{2} ( \frac{1}{{Δ}_{11}} + \frac{1}{{Δ}_{21}} ) + \frac{{g}_{12} {g}_{22}}{2} ( \frac{1}{{Δ}_{12}} + \frac{1}{{Δ}_{22}} ) ] ( {\hat{a}}_{q 1}^{†} {\hat{a}}_{q 2} + {\hat{a}}_{q 1} {\hat{a}}_{q 2}^{†} ) - \frac{1}{2} ( \frac{{g}_{11} {g}_{21}}{{Δ}_{11} {Δ}_{21}} + \frac{{g}_{12} {g}_{22}}{{Δ}_{12} {Δ}_{22}} ) {\sum }_{{i , k = 1}_{i \neq k}}^{2} ( {α}_{qi} ( {\hat{a}}_{qi}^{†} {\hat{a}}_{qi}^{†} {\hat{a}}_{qi} {\hat{a}}_{qk} + H . c . ) ) + {\sum }_{j = 1}^{2} [ \frac{{g}_{1 j} {g}_{2 j}}{{Δ}_{1 j} {Δ}_{2 j}} {α}_{cj} ( {\hat{a}}_{cj}^{†} {\hat{a}}_{cj}^{†} {\hat{a}}_{q 1} {\hat{a}}_{q 2} + H . c . ) ] + {\sum }_{j = 1}^{2} [ \frac{{g}_{1 j} {g}_{2 j}}{{Δ}_{1 j} {Δ}_{2 j}} ( {α}_{q 1} + {α}_{q 2} + 4 {α}_{cj} ) ] {\hat{a}}_{q 1}^{†} {\hat{a}}_{q 1} {\hat{a}}_{q 2}^{†} {\hat{a}}_{q 2} \qquad ( 2 )$$

In equation (2), \tilde{ω}_{qi}, \tilde{α}_{qi}, \tilde{ω}_{cj} and \tilde{α}_{cj} indicates that the frequency and the nonlinearity of the qubit have changed. For brevity, H. c. in parentheses indicates its complex conjugate.

After Schrieffer-Wolff transformation, the interaction between the computational qubit and the coupled qubit is eliminated, and an equivalent coupling between the computational qubits, i.e., â_{q1}⁵⁵⁴ â_{q2}+â_{q1}â_{q2}^{†} type coupling, is generated instead. It is the XY coupling mentioned above as well as â_{gi}^{†}â_{gi}^{†}â_{qi}â_{qk},â_{cj}^{†}â_{cj}^{†}â_{q1}^{†}â_{q1}â_{q2}^{†}â_{q2} coupling induced by the high energy level of the qubit. When adiabatic regulation is adopted, these couplings can be equivalent to the ZZ coupling mentioned above.

As can be seen from equation (2), after two coupled qubits are introduced, in addition to the influence of the computational qubits' own frequency on the XY coupling and the ZZ coupling, the XY coupling and the ZZ coupling between the computational qubits can be regulated by changing the frequencies ω_{c1} and ω_{c2} of the coupled qubits.

Further, in order to eliminate the parasitic coupling between computational qubits, the following conditions need to be satisfied.

The first condition is shown as follows. In order to eliminate the XY coupling between the computational qubits, some restrictions on the frequency of the coupled qubits are required. Specifically, the frequency of one of the coupled qubits can be restricted to be greater than the frequencies of the two computational qubits, and the frequency of the other coupled qubit is less than the frequencies of the two computational qubits. For example, the frequency of the coupled qubit c1 is restricted, so that ω_{c1}>ω_{q1},ω_{q2}, and at the same time, the frequency of the coupled qubit c2 is restricted, so that ω_{c2}<ω_{q1}, ω_{q2}. In this way, when ω_{c1}>ω_{q1},ω_{q2} and ω_{c2}<ω_{q1},ω_{q2}, the XY coupling between the computational qubits induced by the coupled qubit c1 is a negative value; the XY coupling between the computational qubits induced by the coupled qubit c2 is a positive value. At this time, by adjusting ω_{c1} and ω_{c2} independently, the XY coupling between computational qubits can be eliminated.

The second condition is shown as follows. In order to eliminate the ZZ coupling between computational qubits, some restrictions on the nonlinear strength of the coupled qubits are required. Specifically, the nonlinear strength of one of the coupled qubits can be restricted to a positive value, and the nonlinear strength of the other coupled qubit can be restricted to a negative value. For example, the nonlinear strength of the coupled qubit c1 is restricted, so that a_{c1}<0 is a negative value, and at the same time, the nonlinear strength of the coupled qubit c2 is restricted, so that a_{c2}>0. When a_{c1}<0 and a_{c2}>0, the ZZ coupling induced by the coupled qubit c1 is a negative value, and the ZZ coupling induced by the coupled qubit c2 is a positive value. Based on this, by independently adjusting ω_{c1} and, the ZZ coupling between the computational qubits can be eliminated.

The third condition is shown as follows. As an auxiliary qubit, the coupled qubit c1 and the coupled qubit c2 must be prepared to the ground state, to avoid high-level leakage of the coupled qubits, thereby ensuring the fidelity of the quantum gate.

According to the working principle of the superconducting circuit, under the premise of meeting the above three conditions, both the XY coupling and the ZZ coupling between the computational qubits can be hopefully eliminated, so that there is no crosstalk between the computational qubits, thereby creating conditions for realizing a single-bit quantum gate of high fidelity. In addition, if the ZZ coupling is eliminated and only the XY coupling is retained, it can be used to achieve an iSWAP gate of high fidelity. Specifically, by regulating the effective frequencies of the two computational qubits to make them resonate, and then letting the system dynamically evolve for a period of time t, the evolution operator U of the system is shown in the following equation (3):

$$U ( t ) = {e}^{- {ig}_{12} ( {\hat{a}}_{q 1}^{†} {\hat{a}}_{q 2} + {\hat{a}}_{q 1} {\hat{a}}_{q 2}^{†} ) t} \qquad ( 3 )$$

Thee above equation (3) is rewritten into a matrix form as shown in the following equation (4):

$$U ( t ) = \{ \begin{matrix}l & 0 & 0 & 0 \\ 0 & cos ( {\tilde{g}}_{12} t ) & - i sin ( {\tilde{g}}_{12} t ) & 0 \\ 0 & - i sin ( {\tilde{g}}_{12} t ) & cos ( {\tilde{g}}_{12} t ) & 0 \\ 0 & 0 & 0 & 1\end{matrix} \} \qquad ( 4 )$$

When the time t=π/(2\tilde{g}₁₂) is evolved, iSWAP gate can be obtained. In addition, when the time t=π/(4\tilde{g}₁₂) is evolved, the \sqrt{iSWAP} gate can be obtained.

Since the ZZ coupling between computational qubits in the superconducting circuit can be eliminated by modulating the coupled qubits, the fidelity of the iSWAP gate and the \sqrt{iSWAP} gate will be both improved. Further, the iSWAP gate and \sqrt{iSWAP} gate are combined with a single-bit revolving gate, to form a universal quantum gate group for quantum computing.

In addition, since the XY coupling and the ZZ coupling between the computational qubits in the superconducting circuit can be independently regulated, the superconducting circuit can also be used to study the simulation in, for example, the Bose-Hubbard physical model.

### SECOND EMBODIMENT

The present disclosure provides a superconducting quantum chip, including the superconducting circuit architecture including the plurality of coupling devices of the first embodiment. The superconducting circuit architecture includes: a first qubit and a second qubit, and a first coupling device and a second coupling device, in which the first coupling device is coupled to the first qubit and the second qubit through a first connector respectively, and the second coupling device is coupled to the first qubit and the second qubit through a second connector respectively, and in which frequencies of the first qubit and the second qubit are between a frequency of the first coupling device and a frequency of the second coupling device, and a nonlinear strength of the first coupling device and a nonlinear strength of the second coupling device are opposite in sign.

Optionally, the first coupling device and the second coupling device are both qubits prepared to a ground state.

Optionally, the first coupling device includes a first superconducting quantum interference device, and a first capacitor connected in parallel with the first superconducting quantum interference device, in which the first superconducting quantum interference device includes two Josephson junctions connected in parallel, for adjusting the frequency of the first coupling device by applying a magnetic flux; and the second coupling device includes a second superconducting quantum interference device, and a second capacitor connected in parallel with the second superconducting quantum interference device, in which the second superconducting quantum interference device is composed of two Josephson devices connected in series and another Josephson junction connected in parallel therewith, for adjusting the frequency of the second coupling device by applying a magnetic flux.

Optionally, the first qubit includes a third superconducting quantum interference device, for adjusting the frequency of the first qubit by applying a magnetic flux; and the second qubit includes a fourth superconducting quantum interference device, for adjusting the frequency of the second qubit by applying a magnetic flux.

Optionally, the third superconducting quantum interference device and the fourth superconducting quantum interference device both include two Josephson junctions connected in parallel.

Optionally, the first qubit and the second qubit both include a noise reduction component, for reducing a noise of charge fluctuations in an environment where the qubit is located.

Optionally, the first qubit further includes a third capacitor connected in parallel with the third superconducting quantum interference device, for reducing a noise of charge fluctuations in an environment where the qubit is located; and the second qubit further comprises a fourth capacitor connected in parallel with the fourth superconducting quantum interference device, for reducing a noise of charge fluctuations in an environment where the qubit is located.

Optionally, the superconducting circuit architecture further includes a third coupling device, in which the third coupling device is coupled to the first qubit and the second qubit through a third connector respectively.

The superconducting circuit architecture further includes: a third qubit, a fourth coupling device, and a fifth coupling device, in which the fourth coupling device is coupled to a target computational qubit and the third qubit through a fourth connector respectively, and the fifth coupling device is coupled to the target computational qubit and the third qubit through a fifth connector respectively, and in which the target computational qubit is one of the first qubit and the second qubit.

It should be noted that the superconducting circuit architecture in the above superconducting quantum chip is similar in structure to the superconducting circuit architecture in the first embodiment, and has the same advantageous effects as the superconducting circuit architecture in the first embodiment, which will not be repeated herein. For the technical details that are not disclosed in the embodiment of the superconducting quantum chip of the present disclosure, those skilled in the art would understand by referring to the description of the superconducting circuit architecture in the first embodiment. In order to save space, it will not be repeated herein.

### THIRD EMBODIMENT

The present disclosure provides a superconducting quantum computer. The superconducting quantum computer includes a superconducting quantum chip, and may further include a control device and a reading device connected to the superconducting quantum chip. The superconducting quantum chip includes the superconducting circuit architecture including the plurality of coupling devices of the first embodiment. The superconducting circuit architecture includes: a first qubit and a second qubit, and a first coupling device and a second coupling device. The first coupling device is coupled to the first qubit and the second qubit through a first connector respectively, and the second coupling device is coupled to the first qubit and the second qubit through a second connector respectively. The frequencies of the first qubit and the second qubit are between a frequency of the first coupling device and a frequency of the second coupling device, and a nonlinear strength of the first coupling device and a nonlinear strength of the second coupling device are opposite in sign.

Optionally, the first coupling device and the second coupling device are both qubits prepared to a ground state.

Optionally, the first coupling device includes a first superconducting quantum interference device, and a first capacitor connected in parallel with the first superconducting quantum interference device. The first superconducting quantum interference device includes two Josephson junctions connected in parallel, for adjusting the frequency of the first coupling device by applying a magnetic flux. The second coupling device comprises a second superconducting quantum interference device, and a second capacitor connected in parallel with the second superconducting quantum interference device. The second superconducting quantum interference device is composed of two Josephson devices connected in series and another Josephson junction connected in parallel therewith, for adjusting the frequency of the second coupling device by applying a magnetic flux.

Optionally, the first qubit includes a third superconducting quantum interference device, for adjusting the frequency of the first qubit by applying a magnetic flux; and the second qubit includes a fourth superconducting quantum interference device, for adjusting the frequency of the second qubit by applying a magnetic flux.

Optionally, the third superconducting quantum interference device and the fourth superconducting quantum interference device both include two Josephson junctions connected in parallel.

Optionally, the first qubit and the second qubit both include a noise reduction component, for reducing a noise of charge fluctuations in an environment where the qubit is located.

Optionally, the first qubit further includes a third capacitor connected in parallel with the third superconducting quantum interference device, for reducing a noise of charge fluctuations in an environment where the qubit is located; and the second qubit further comprises a fourth capacitor connected in parallel with the fourth superconducting quantum interference device, for reducing a noise of charge fluctuations in an environment where the qubit is located.

Optionally, the superconducting circuit architecture further includes a third coupling device, in which the third coupling device is coupled to the first qubit and the second qubit through a third connector respectively.

Optionally, the superconducting circuit architecture further includes a third qubit, a fourth coupling device, and a fifth coupling device, in which the fourth coupling device is coupled to a target computational qubit and the third qubit through a fourth connector respectively, and the fifth coupling device is coupled to the target computational qubit and the third qubit through a fifth connector respectively, and in which the target computational qubit is one of the first qubit and the second qubit.

It should be noted that the superconducting circuit architecture in the above superconducting quantum computer is similar to the superconducting circuit architecture in the first embodiment, and has the same beneficial effects as the superconducting circuit architecture in the first embodiment, which will not be repeated herein. For the technical details that are not disclosed in the embodiments of the superconducting quantum computer of the present disclosure, those skilled in the art would understand by referring to the description of the superconducting circuit architecture in the first example. In order to save space, it will not be repeated herein.

The above specific embodiments do not constitute a limitation on the protection scope of the present disclosure. Those skilled in the art should understand that various modifications, combinations, sub-combinations and substitutions can be made according to design requirements and other factors. Any amendments, equivalent substitutions and improvements made within the spirit and principle of the present disclosure shall be included in the protection scope of the present disclosure.

What is claimed is:

1. A superconducting circuit architecture comprising a plurality of coupling devices, comprising a first qubit and a second qubit, and a first coupling device and a second coupling device,
wherein the first coupling device is coupled to the first qubit and the second qubit through a first connector, and the second coupling device is coupled to the first qubit and the second qubit through a second connector, and
wherein frequencies of the first qubit and the second qubit are between a frequency of the first coupling device and a frequency of the second coupling device, and a nonlinear strength of the first coupling device and a nonlinear strength of the second coupling device are opposite in sign.

2. The superconducting circuit architecture of claim 1, wherein the first coupling device and the second coupling device are both qubits prepared to a ground state.

3. The superconducting circuit architecture of claim 2, wherein the first coupling device comprises a first superconducting quantum interference device, and a first capacitor connected in parallel with the first superconducting quantum interference device, wherein the first superconducting quantum interference device comprises two Josephson junctions connected in parallel, for adjusting the frequency of the first coupling device by applying a magnetic flux; and
the second coupling device comprises a second superconducting quantum interference device, and a second capacitor connected in parallel with the second superconducting quantum interference device, wherein the second superconducting quantum interference device is composed of two Josephson devices connected in series and another Josephson junction connected in parallel therewith, for adjusting the frequency of the second coupling device by applying a magnetic flux.

4. The superconducting circuit architecture of claim 1, wherein the first qubit comprises a third superconducting quantum interference device, for adjusting the frequency of the first qubit by applying a magnetic flux; and
the second qubit comprises a fourth superconducting quantum interference device, for adjusting the frequency of the second qubit by applying a magnetic flux.

5. The superconducting circuit architecture of claim 4, wherein the third superconducting quantum interference device and the fourth superconducting quantum interference device both comprise two Josephson junctions connected in parallel.

6. The superconducting circuit architecture of claim 4, wherein the first qubit and the second qubit both comprise a noise reduction component, for reducing a noise of charge fluctuations in an environment where the qubit is located.

7. The superconducting circuit architecture of claim 4, wherein the first qubit further comprises a third capacitor connected in parallel with the third superconducting quantum interference device, for reducing a noise of charge fluctuations in an environment where the qubit is located; and
the second qubit further comprises a fourth capacitor connected in parallel with the fourth superconducting quantum interference device, for reducing a noise of charge fluctuations in an environment where the qubit is located.

8. The superconducting circuit architecture of claim 1, wherein the superconducting circuit architecture further comprises: a third coupling device,
wherein the third coupling device being coupled to the first qubit and the second qubit through a third connector.

9. The superconducting circuit architecture of claim 1, wherein the superconducting circuit architecture further comprises a third qubit, a fourth coupling device, and a fifth coupling device;
wherein the fourth coupling device is coupled to a target computational qubit and the third qubit through a fourth connector, and the fifth coupling device is coupled to the target computational qubit and the third qubit through a fifth connector; and
wherein the target computational qubit is one of the first qubit and the second qubit.

10. A superconducting quantum chip, comprising the superconducting circuit architecture comprising the plurality of coupling devices of claim 1.

11. A superconducting quantum computer, comprising the superconducting quantum chip of claim 10.
